(19) United States
(12) Patent Application Publication
(10) Pub. No.: US 2009/0155488 A1
(43) Pub. Date: Jun. 18, 2009

(54) SHOWER PLATE ELECTRODE FOR PLASMA CVD REACTOR

(75) Inventors: Ryu Nakano, Tokyo (JP); Hideaki Fukuda, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: ASM JAPAN K.K., Tokyo (JP)

(21) Appl. No.: 11/959,410

(22) Filed: Dec. 18, 2007

(51) Int. Cl. C23C 16/513; B08B 7/00

(52) U.S. Cl. 427/569; 134/1.1; 427/248.1; 118/723 R

(57) ABSTRACT

Methods and apparatuses for plasma chemical vapor deposition (CVD). In particular, a plasma CVD apparatus having a cleaning function, has an improved shower plate with holes having a uniform cross-sectional area to yield a high cleaning rate. The shower plate may serve as an electrode, and may have an electrically conductive extension connected to a power source. The shower plate, through which both cleaning gases and reaction source gases flow, may include a hole machined surface area with a size different than conventionally used to ensure a good film thickness uniformity during a deposition process. The size of the hole machined surface area may vary based on the size of a substrate to be processed, or the size of the entire surface of the shower plate.

### BACKGROUND OF THE INVENTION

1. Field of the Invention

The present invention relates to methods and apparatuses for plasma chemical vapor deposition (CVD). In particular, the present invention relates to shower plates.

2. Description of the Related Art

Generally, a plasma treatment apparatus is used for forming or removing films or for reforming the surface of an object-to-be-processed. In particular, thin film formation (by plasma CVD) on semiconductor wafers such as silicon or glass substrates or thin film etching is useful for manufacturing memories, semiconductor devices such as CPU's, or liquid crystal displays (LCDs).

CVD apparatuses have been traditionally used for forming insulation films such as silicon oxide (SiO), silicon nitride (SiN), silicon carbide (SiC) and silicon oxide carbide (SiOC), as well as conductive films such as tungsten silicide (WSi), titanium nitride (TiN) and aluminum (Al) alloy on silicon or glass substrates. To form these films, multiple reaction gases having various constituents are brought into a reaction chamber. In a plasma CVD apparatus, these reaction gases are excited into a plasma, such as by radio-frequency or microwave energy, and chemically react to form a desired thin film on a substrate supported by a susceptor.

To enter into a reaction chamber, reaction gases may flow from a storage container, through a conduit and through a shower plate, before reacting to deposit a film on a substrate, such as a silicon wafer. The shower plate has a top surface and a bottom surface, and includes a number of holes that extend through the shower plate from the top surface to the bottom surface. Different gases, including reactant and cleaning gases, flow through the shower plate holes before being distributed onto the substrate. The purpose of the shower plate is to uniformly distribute the reactant gases across the substrate surface to promote a more uniform deposition of a film. To promote film thickness uniformity, the holes of the shower plate are typically constricted at one end, such that the holes have a larger inlet, or gas point of entry, than outlet, or gas point of exit. The shower plate may also serve as an electrode, such as in a parallel plate CVD apparatus, to excite gases into plasma within the reaction chamber during the wafer processing stage.

Products generated by a plasma chemical reaction in a reaction chamber during wafer processing result in unwanted deposits accumulating on inner walls of the reaction chamber and on the surface of the susceptor. As thin film formation is repeated, such deposits gradually accumulate inside the plasma CVD apparatus. Subsequently, the deposits exfoliate from the inner walls and the susceptor surface and float inside the reaction chamber. The deposits then adhere onto substrates as foreign objects and cause impurity contamination, which results in defects in processed substrates.

To remove such unwanted deposits adhered to the inner walls of the reaction chamber, a plasma cleaning method has been used. In one such plasma cleaning method, a cleaning gas, such as NF₃, is excited to a plasma state by radio-frequency power outside of the reaction chamber, such as inside an external discharge chamber isolated from the reaction chamber. The NF₃ dissociates, and an active fluorine species forms, which can react with the unwanted deposits. The active fluorine species are then brought into the reaction chamber where they decompose and remove extraneous deposits adhered to the inner wall surface of the reaction chamber. In one example, using a flow controlled NF₃ cleaning gas to remove extraneous matter adhered to the inner wall surface of the reaction chamber resulted in an effective cleaning rate of approximately 1.5 μm/min.

In recent years, semiconductor substrates have become larger and continue to grow. Due to the increasing size of the substrates, reaction chambers have also increased in capacity, resulting in an increase in the amount of unwanted deposits that adhere to reactor chamber walls. With the increase in the amount of deposits needing to be removed, the time for cleaning tends to increase. Because of this increased cleaning time, the number of substrates processed per unit time (throughput) declines. A need therefore exists to increase the cleaning efficiency of the reaction chamber to increase throughput.

### SUMMARY OF THE INVENTION

In one aspect, the present application provides a method of cleaning a CVD processing chamber after processing a wafer, using a remote plasma discharge device. The processed wafer is removed from a susceptor in the chamber. Cleaning gas is supplied to the remote plasma discharge device. Plasma energy is used to activate the cleaning gas in the remote plasma discharge device. The activated cleaning gas is then conveyed into the chamber and through a plurality of holes of a shower plate facing the susceptor. The holes extend completely through the shower plate and each have a uniform cross-sectional area. A diameter of a smallest circular area of the shower plate having all of the holes is 0.95 to 1.05 times a diameter of a surface area of the wafer.

In another aspect, the present application provides a method of processing a substrate in a chamber. A substrate is placed on a susceptor in the chamber. Reaction gas is then supplied into the chamber through a plurality of holes of a shower plate facing the susceptor. The holes extend completely through the shower plate, and each have a uniform cross-sectional area. A diameter of a smallest circular area of the shower plate having all of the holes is 0.95 to 1.05 times a diameter of a side of the substrate.

Another aspect of the present application includes a plasma CVD apparatus having a plasma CVD reaction chamber. A susceptor for supporting a substrate is disposed inside the reaction chamber and configured to be used as a first electrode to generate a plasma. A shower plate used as a second electrode to generate the plasma faces the susceptor and has a plurality of holes extending through the shower plate, the holes each having a uniform cross-sectional area. A diameter of a smallest circular area of the shower plate having all of the holes is 0.95 to 1.05 times a diameter of largest possible substrate that can fit within a confining structure of the susceptor. The shower plate is electrically connected to one or more power sources.

In another aspect, a shower plate for use in a plasma CVD device includes a plate having an electrically conductive extension configured to be connected to a power source to enable the plate to act as an electrode. The plate includes a plurality of holes extending through the plate and each have a uniform cross-sectional area.

While the present application has been described with respect to certain embodiments thereof, it will be understood by one skilled in the art that changes in forms and details may be made without departing from the spirit and scope of the invention. It is therefore intended that the present invention is not limited to the exact forms and details described in the summary of the invention.

It will be appreciated by those skilled in the art that various omissions, additions and modifications may be made to the processes and apparatuses described without departing from the scope of the invention, and all such modifications and changes are intended to fall within the scope of the invention.

### BRIEF DESCRIPTION OF THE DRAWINGS

These and other features, aspects and advantages of the various devices, systems and methods presented herein are described with reference to drawings of certain embodiments, which are intended to illustrate, but not to limit, such devices, systems, and methods. The drawings include eleven figures. It is to be understood that the attached drawings are for the purpose of illustrating concepts of the embodiments discussed herein and may not be to scale.

FIG. 1 is a schematic view of a plasma CVD apparatus according to one embodiment of the present application.

FIG. 2A is a vertical sectional view of a conventional shower plate illustrating the shape of the holes in the plate.

FIG. 2B is a vertical sectional view of a shower plate according to one embodiment of the present application.

FIG. 3A is a top view and a side sectional view of a shower plate according to one embodiment of the present application.

FIG. 3B is a top view of a spiral pattern of shower plate holes according to one embodiment of the present application.

FIG. 4 is a graph showing the relationship between cleaning rate and film thickness uniformity with respect to the diameter of the hole machining area of a shower plate.

FIG. 5 is a side view of the inside of a reaction chamber of an embodiment of the present application.

FIG. 6A is a chart showing deposition conditions of a TEOS and oxygen reaction for one experiment using a conventional shower plate and three different experiments using a shower plate of the present application.

FIG. 6B is a chart comparing the cleaning rate and deposited film thickness uniformity resulting from the deposition conditions shown in FIG. 6A.

FIG. 7A is a side view of an upper portion of a conventional plasma CVD reaction chamber, illustrating the presence of parasitic plasma.

FIG. 7B is a side view of an upper portion of a plasma CVD reaction chamber according to an embodiment of the present application.

FIG. 8 is a graph showing the presence or absence of parasitic plasma generated during wafer processing based on combinations of reaction chamber pressure and high RF power, when using a conventional shower plate with a conventional ceramic conduit, an inventive shower plate with a conventional ceramic conduit, and an inventive shower plate with a long ceramic conduit in accordance with an embodiment of the invention.

### DETAILED DESCRIPTION OF THE PREFERRED EMBODIMENTS

The present application relates to a plasma chemical vapor deposition (CVD) apparatus having a remote plasma generator for remote activation of a cleaning gas. More particularly, the application relates to a new shower plate having improved holes with a uniform cross-sectional area to improve the reactor cleaning rate in order to increase throughput.

In a parallel-plate plasma CVD apparatus, the shower plate serves as an upper electrode for in situ plasma generation in reactant gases. By modifying the holes of the shower plate, including the dimensions of the holes, an improved reactor cleaning rate can be achieved. Moreover, careful selection of the size of the “hole machining area,” in conjunction with the modified holes, also leads unexpectedly to improved uniformity of films deposited during wafer processing, and in some cases an increased cleaning rate. As used herein, the hole machining area refers to the smallest circular area enclosing all of the holes of the shower plate. These improvements, as well as others disclosed below, were discovered by conducting experiments using remote plasma cleaning for a parallel plate CVD apparatus. In particular, these experiments were conducted on 300 mm substrates using an ASMI Eagle® 12 plasma CVD apparatus sold by ASM Japan K.K. of Tokyo, Japan. For reference, the Eagle® 12 plasma CVD apparatus is described in U.S. Patent Publication No. 2007-0248767 A1, filed on Apr. 6, 2007.

As noted above, one conventional apparatus (see U.S. Pat. No. 6,736,147) achieved a cleaning rate of approximately 1.5 μm/min. However, as reaction chambers become larger due to increased wafer sizes, the cleaning rate should be improved to ensure a high throughput. Embodiments of the present application increase the cleaning rate by modifying the holes of the shower plate such that they have a uniform cross-sectional area, preferably one that is circular, as would result from the use of a drill bit.

Embodiments of the present application provide a plasma CVD apparatus that conducts a cleaning function to remove unwanted deposits at a high chamber-cleaning rate, and a method for conducting such cleaning, regardless of the size of a reaction chamber or wafer to be processed. By having a high chamber-cleaning rate, reactor downtime is reduced and the throughput of the apparatus is increased.

Embodiments of the present application provide an improved shower plate having holes with a uniform cross-sectional area, the shower plate preferably serving as an upper electrode with a susceptor preferably serving as a lower electrode in a parallel plate CVD apparatus. In some embodiments, an electrically conductive extension leading to a power source is connected to the shower plate. The power may be provided by, for example, a radio-frequency (RF) power source or a set of high and low RF power sources that enable the shower plate to act as an electrode.

Embodiments of the present application provide a plasma CVD apparatus having an improved shower plate that facilitates self-cleaning at a high chamber-cleaning rate, yet does not significantly sacrifice deposited film thickness uniformity during the wafer processing stage. It is one goal of the present application to ensure that, in certain embodiments, all improvements to the conventional plasma CVD apparatus meet industrial manufacturing uniformity standards.

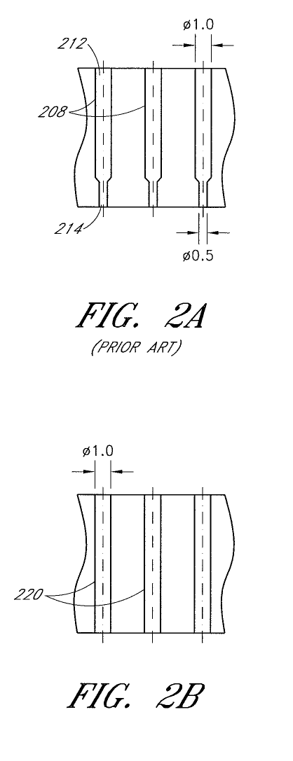

To achieve the above-mentioned objects, in an embodiment, the present application provides a plasma CVD apparatus comprising: (i) a reaction chamber; (ii) a susceptor for placing thereon a substrate, said susceptor being disposed inside the reaction chamber and constituting one of two electrodes for generating an in situ plasma; (iii) a shower plate for discharging a reaction gas or a cleaning gas inside the reaction chamber, said shower plate being disposed in parallel to the susceptor and constituting the other electrode for generating the plasma; and (iv) a power source (e.g., radio-frequency) electrically connected to the shower plate. By improving features of the shower plate, namely the holes of the shower plate that extend from the bottom to the top surface of the plate, a higher cleaning rate can be achieved. In one embodiment, a shower plate has straight, uniform through holes that allow for a higher cleaning rate than conventional shower plates, which have holes that are restricted. For example, one particular conventional shower plate has holes that are 1.0 mm in diameter with a 0.5 mm restriction at a bottom surface of the plate (as shown in FIG. 2A). By modifying the holes used in the shower plate, such that they are straight and have a uniform cross-sectional area, the reaction chamber may have a cleaning rate greater than 2200 nm/min. For example, in one embodiment, the shower plate has holes of uniform diameter (e.g., 1.0 mm).

In the above, in consideration of preventing so-called parasitic plasma (abnormal plasma) that forms above the shower plate from flowing through the shower plate and interfering with the deposition process, the plasma CVD apparatus may further comprise a ceramic conduit (through which both reactant and cleaning gases may flow) mounted to the top wall of the chamber, the conduit having a length greater than 35 mm. The significance of such a conduit is explained below.

In one embodiment, in consideration of preventing depreciating film thickness uniformity due to the modification of the holes to have a uniform cross-sectional area, the hole machining area of the shower plate is also modified. In conducting the above mentioned experiments, it was unexpectedly found that by reducing the size of the hole machining area (which was conventionally about 18.1% larger in surface area and about 8.7% larger in diameter), film thickness uniformity could be improved. In one embodiment, the reaction chamber has a shower plate with a hole machining area diameter that is 0.95 to 1.05 times a diameter of one side of the substrate to be processed. This corresponds to a circular hole machining area that is 0.90 to 1.10 times an area of one side of the substrate to be processed. Not only is the ratio of the hole machining surface area to the surface area of a side of the substrate related to the film thickness uniformity of a film deposited on the substrate, it also affects the cleaning rate. It has been unexpectedly found that reducing the hole machining area can significantly improve the cleaning rate. To further ensure good film thickness uniformity, in another embodiment, the modified holes of the shower plate are arranged in a spiral pattern along the surface of the shower plate.

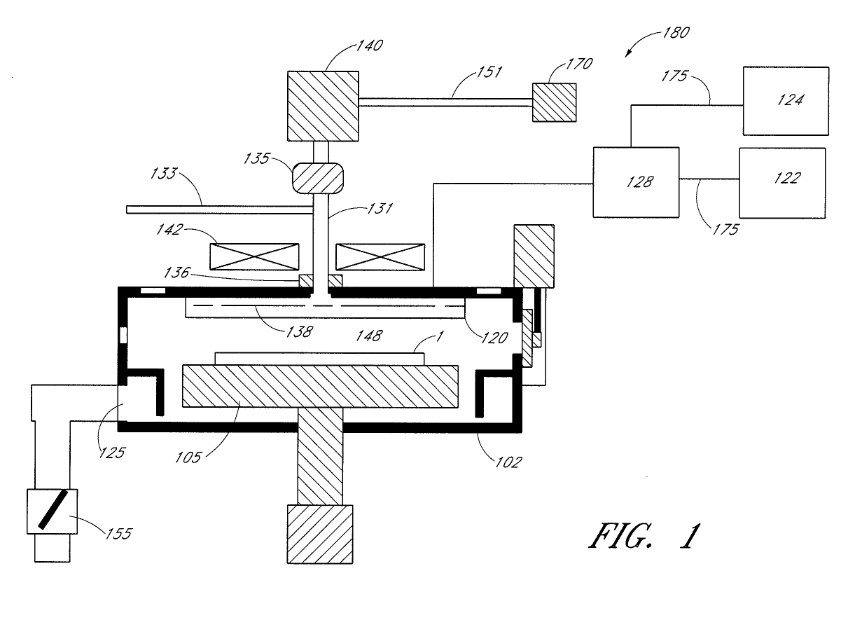

FIG. 1 illustrates a parallel-plate plasma enhanced CVD (PECVD) apparatus 180 having a remote plasma cleaning device in accordance with one embodiment. It will be understood that alternative plasma CVD apparatuses may be used. The plasma CVD apparatus 180 may be used for forming or removing films, or for reforming the surface of substrate 1. The plasma CVD apparatus 180 includes a reaction chamber 102 housing a susceptor 105 for placing thereon a substrate 1 such as a glass or silicon substrate. On one side wall of the reaction chamber 102 is an exhaust port 125. In a parallel-plate CVD apparatus, the susceptor 105 serves as a lower electrode. The susceptor 105 may be made of a ceramic or aluminum alloy, or any other material typically used to support substrates. If the susceptor 105 is to be used as an electrode for in situ plasma generation, it is understood that the material used must be consistent with the conductive functions of an electrode. In this case, the susceptor 105 is preferably electrically grounded. In some embodiments, a resistor heating device used to heat the susceptor 105 and substrate 1 is embedded within the susceptor 105. In other embodiments, radiant heat lamps are used to heat the susceptor 105 and substrate 1. It will be understood that different types and combinations of heating devices can be employed, and the particular mode of heating is not critical to the invention

At a position opposite to and facing the susceptor 105 is a shower plate 120 having a plurality of holes that extend through the shower plate, from its bottom surface to its top surface. The shower plate 120 can be made of aluminum or aluminum alloy, or other suitable metal. In one embodiment, the shower plate 120 has a planar bottom surface that is generally parallel with an upper surface of the susceptor 105. In other embodiments, the bottom surface of the shower plate 120 may be curved, or a combination of both planar and curved surfaces. The shower plate 120 preferably serves as an upper electrode for cooperating with a lower electrode (such as the susceptor 105), to generate in situ plasma out of reaction gases. The plate 120 is preferably configured to cause the reaction gases to deposit a substantially uniform film onto the substrate, by which it is meant that the holes are arranged throughout the horizontal dimensions of a substrate 1 supported on the susceptor 105. On the upper side of the shower plate 120, an air-cooling fan 142 may be placed to prevent temperature changes of the shower plate 120.

To generate the plasma, power sources 122 and 124 (e.g., radio-frequency) are electrically connected to the shower plate 120 via a matching circuit 128, which is connected to power sources 122 and 124 by coaxial RF cables 175. These power sources 122 and 124 generate plasma by supplying frequencies from, in certain embodiments, hundreds of kHz to tens of MHz. Although both power sources 122 and 124 may have the same frequencies, in a preferred embodiment the power sources have different frequencies, one high and one low, to improve the controllability of film quality in wafer processing. One skilled in the art will also appreciate that other power sources may be used besides radio-frequency power sources, such as microwave power sources.

The reaction gases used for wafer processing can be stored in a separate container and can be supplied to the shower plate 120 via a conduit such as a deposition gas delivery pipe 133. In the illustrated embodiment, before reaching the shower plate 120, the reaction gases pass through a buffer plate 138, which is used to uniformly distribute the gases across the shower plate 120. After passing through the buffer plate 138, the reaction gases flow through the holes of the shower plate 120 and into a central region 148 of the reaction chamber 102. Once inside the reaction chamber 102, the reaction gases are excited into a plasma state via the power sources 122 and 124, resulting in a chemical reaction that leaves a film deposited on the surface of the substrate. The products generated by the plasma reaction chamber also accumulate on inner walls of the reaction chamber 102 and on the surface of the susceptor 105 and shower plate 120, and must be cleaned periodically to ensure that the unwanted deposits do not contaminate the processed substrates.

Although various reaction gases may be used for wafer processing of the invention, the above mentioned experiments used tetra-ethyl-ortho-silicate, or equivalently tetra-ethoxy-silane (TEOS), and oxygen (O₂) to form a TEOS oxide film onto a silicon substrate. TEOS is commonly used with oxygen (O₂) to form an oxide layer over a substrate. Typical conditions for this process are: a TEOS flow rate of 250 sccm, an O₂ flow rate of 2.3 slm, a distance between an upper electrode 120 and lower electrode 105 of 10 mm, a reaction chamber pressure of 400 Pa, a high radio-frequency power (13.56 MHz) of 600 W and a low radio-frequency power (430 kHz) of 400 W, a susceptor 105 temperature of 360° C., a shower plate 120 temperature of 150° C., and a reaction chamber 102 inner wall temperature of 140° C.

With continued reference to FIG. 1, extending from an upper opening of the reaction chamber 102 is a conduit 131 through which reaction and/or cleaning gases may flow. The conduit 131 may be made of a metal, such as aluminum, and may be connected to an isolation valve 135 and a second conduit 136. The second conduit is located above the shower plate 120 and may be composed of dielectric materials including ceramic materials. The remote plasma discharge device 140 is connected to a second conduit such as a cleaning gas delivery pipe 151. A cleaning gas can be delivered from a cleaning gas source 170 and can be conveyed into the remote plasma discharge device 140 via the cleaning gas delivery pipe 151. Although various cleaning gases may be used, in one embodiment the cleaning gas comprises a fluorine-containing gas mixed with an inert carrier gas or oxygen, such as C₂F₆+O₂, NF₃+Ar or F₂+Ar. Within the remote plasma discharge device 140, plasma energy activates the cleaning gas, resulting in active cleaning species that flow through the conduit 131 and the shower plate 120 into the reaction chamber 102. The active cleaning gas species chemically react with the unwanted deposits adhered to the inner walls of the reaction chamber 102 and the surfaces of the shower plate 120. This causes the unwanted deposits to become gasified and then discharged out of an exhaust port 125 of the reaction chamber, and past a conductance regulation valve 155 by a vacuum pump.

FIGS. 2A and 2B illustrate shower plate holes through which reaction gases and cleaning gases flow before entering a reaction chamber. These holes are preferably machined into the shower plate, and occupy an area of the shower plate which is referred to herein as the “hole machining area.” FIG. 2A illustrates conventional holes, as used in the prior art, whereas FIG. 2B illustrates one embodiment of improved holes of the present invention.

FIG. 2A illustrates conventional holes 208 having inlets 212 and outlets 214 of two different sizes. As shown in FIG. 2A, the diameter of inlets is greater than the diameter 214 of outlets by a ratio of 2:1, the inlet diameter being 1.0 mm, while the outlet diameter is 0.5 mm. These conventional holes with different inlet and outlet diameters have been found to increase deposited film thickness uniformity. For example, in experiments conducted in which TEOS and O₂ were used as reactant gases to deposit TEOS oxide on a substrate, the film thickness uniformity using conventional holes 208 was approximately ±1.8%, which is better than the typical uniformity (±3.0%) required in industrial manufacturing. However, using the conventional holes resulted in a reactor cleaning rate of only about 1.40 μm/min during the cleaning process.

FIG. 2B illustrates one embodiment of shower plate holes 220 of the present application. The illustrated shower plate holes 220 have a uniform cross-sectional shape along their length, or, in the case of circular holes, a uniform diameter. These improved shower plate holes 220 are preferably straight and vertically oriented, and extend from the bottom surface to the top surface of the shower plate. The holes 220 can be spaced at a distance between 2 mm and 5 mm from each other. The shower plate holes 220 can each have a uniform diameter between 0.5 mm and 1.0 mm, although other sizes are possible. In a preferred embodiment, and as shown in FIG. 2B, the modified holes 220 have a uniform diameter of 1.0 mm.

By having shower plate holes of uniform diameter, the cleaning rate is improved over conventional shower plates. For example, while the cleaning rate using the conventional holes 208 of FIG. 2A was found to be approximately 1.40 μm/min, the cleaning rate using the improved holes 220 of FIG. 2B under similar conditions was found to be approximately 2.36 μm/min. In some embodiments, and as in this example, the cleaning rate exceeds 2.20 μm/min. Another benefit of using uniform diameter holes 220 is that they are more cost effective because they are much easier to machine than the conventional holes 208 having two different diameters.

The higher cleaning rate achieved by the modified, uniform diameter holes can be explained by the relationship between an Arrhenius reaction rate and temperature during a chemical reaction. The relationship between an Arrhenius reaction rate and temperature can be expressed by the following formula: k=A exp^{(-E/RT)}, where k is a rate constant, A is a frequency factor, E is an activation energy, R is the gas constant, and T is an absolute temperature. For purposes of this application, k represents a cleaning rate, while A depends mainly on the partial pressure of fluorine radicals (F*). The formula indicates that increasing A and T will yield a higher cleaning rate k. One way to increase A is to increase the number of active fluorine radicals, which will increase the cleaning rate.

It was found that an increase in partial pressure of the fluorine radicals F* could be achieved by increasing gas conductance through the shower plate. In conventional shower plates having holes with reduced diameter as shown in FIG. 2A, conductance decreases. This is because many collisions occur between the active fluorine radicals and the inner walls of the holes due to the restricted diameter of the walls, causing the active fluorine radicals to deactivate from active F* to deactive F2. Because deactive fluorine members do not effectively react with unwanted film deposits, the cleaning rate decreases. Therefore, improving the shower plate to have uniform cross-section through holes reduces the number of collisions between the active fluorine radicals and inner hole walls, which results in a lesser number of deactivated fluorine radicals than in conventional shower plates and an increase in chamber cleaning rate.

Although providing modified holes 220 results in an improved cleaning rate over the conventional holes 208, it can also cause the thickness uniformity of the deposited film to fall below industrial manufacturing standards, which is why conventional restricted holes 208 have been used. Conventionally, for processing 300 mm wafers, a shower plate having a hole machining area with a diameter of approximately 326 mm has been used. In experiments using TEOS and O₂ as reactant gases and using modified holes 220 of FIG. 2B, the film thickness uniformity of the deposited TEOS oxide was ±3.41%, which is much worse than when conventional holes 208 are used. This uniformity is also worse than the typical uniformity required (±3.0%) in industrial manufacturing. Consequently, the benefit of a high cleaning rate by having uniformly sized through holes 220 can only be retained if the depreciated film uniformity can be improved to meet industrial manufacturing standards. In this regard, it has been found that changing the size of the hole machining area of the shower plate can improve the film thickness uniformity without sacrificing the benefit of a high cleaning rate. In some embodiments, reducing the size of the diameter of the hole machining area below the conventional size (approximately 326 mm) also resulted in even higher cleaning rates.

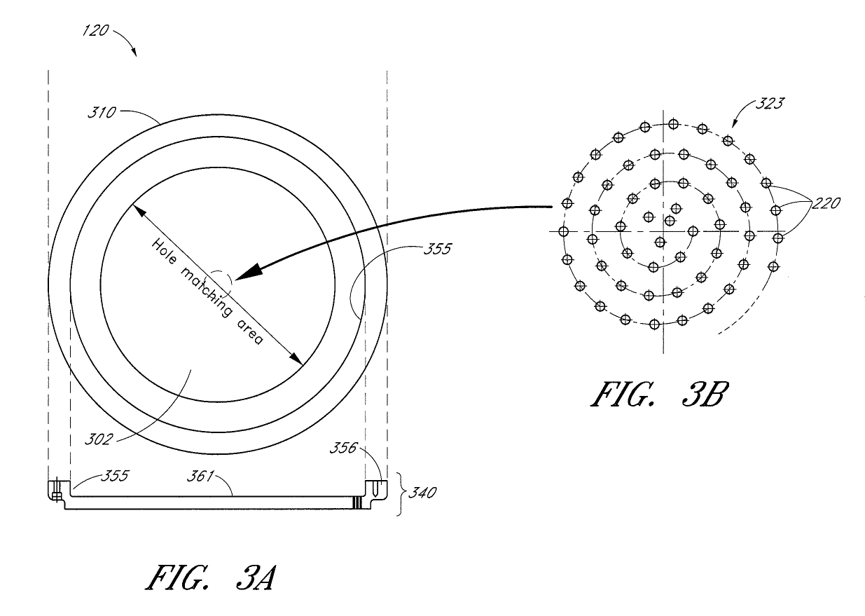

FIG. 3A illustrates, by way of a top view and side sectional view, one embodiment of a shower plate 120 of the present application, having a carefully selected hole machining area size. Although the hole machining area may be of various shapes, it is preferably a circular area 302 encompassing all of the holes 220 (FIG. 2B) in view of the fact that commercial wafers are likewise circular. In a preferred embodiment, the hole machining area 302 is the smallest circular area encompassing all of the holes 220. Experiments conducted show that by changing the size of the hole machining area in relation to the area of a surface of the substrate, a deposition thickness uniformity that meets industrial standards can be maintained. Without changing the size of the hole machining area, merely changing the holes such that they have a uniform cross-sectional area would result in a greater cleaning rate, but a depreciated film thickness uniformity. Thus, the ratio of the size of the hole machining area to the size of a side of the substrate is preferably selected to fall within a certain range. In the illustrated embodiment, the shower plate 120 is not completely flat, but rather has raised vertical shoulder 356 with an inner vertical wall 355 that defines a recess 361. In one embodiment, the diameter of the inner vertical wall 355 that defines the recess is 350 mm.

The hole machining area 302 comprises only a percentage of the size of the shower plate, the boundary of which is shown at 310. Areas of the shower plate which are not occupied by the hole machining area 302 do not have holes for through-flow of gas. The area surrounding the hole machining area 302, which includes the shoulder 356, is designated as 312.

FIG. 3B illustrates one embodiment of an arrangement of holes 220 of the modified shower plate 120 of FIG. 3A, in which the holes form a spiral pattern 323 on a surface of the shower plate. The spiral pattern 323 provides an improvement over non-spiral patterns by helping to ensure a more uniform film thickness deposition than other patterns. However, it is understood that shower plates with varying patterns, spiral or non-spiral, may be used and still achieve a thickness uniformity that meets industrial manufacturing standards.

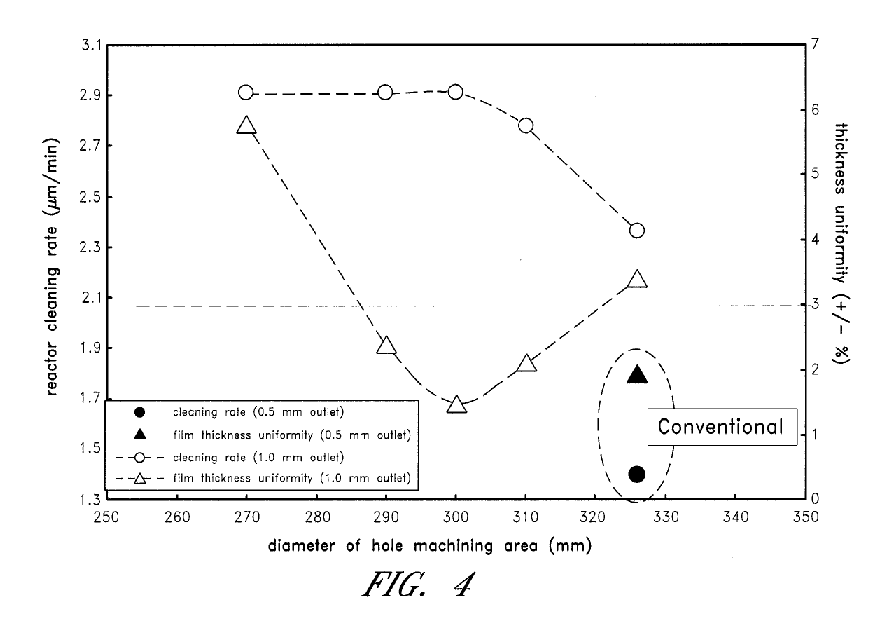

FIG. 4 is a graph showing the dependence of the reactor cleaning rate and deposited film thickness uniformity on the diameter of a circular hole machining area 302 (FIG. 3A) with holes 220 (FIG. 2B) having a uniform 1.0 mm diameter for a 300 mm wafer. For reference, FIG. 4 also shows the cleaning rate and film thickness uniformity obtained using conventional holes 208 (FIG. 2A) for a conventionally sized hole machining area 302. A conventional hole machining area 302 has a diameter of about 326 mm.

FIG. 4 illustrates the problem of using a shower plate having conventional holes in a hole machining area with a diameter of approximately 326 mm, and switching to uniform 1.0 mm diameter holes without modifying the hole machining area. In this situation, while the cleaning rate increases from approximately 1.4 μm/min to 2.4 μm/min, the film thickness uniformity undesirably increases from approximately ±2% to greater than ±3%, which is unacceptable under industrial manufacturing standards. By decreasing the hole machining area, as shown in FIG. 4, an unexpected solution to the film thickness uniformity problem was found. It was also unexpectedly found that by decreasing the hole machining area and using straight, uniform diameter through holes actually improved the cleaning rate.

The graph of FIG. 4 shows how hole machining areas having various diameters (270, 290, 300, and 310 mm) were tested to determine the optimal diameter range so as to achieve a high cleaning rate and satisfactory film uniformity of less than ±3.0%, and even more preferably less than ±2.0%. As shown in FIG. 4, it was found that a hole machining area having a diameter between 285 mm and 310 mm results in an excellent reactor cleaning rate (much better than achieved by conventional shower plates), and a good film thickness uniformity below ±3.0%. More specifically, a hole machining area having a diameter of 300 mm was found to produce a very high cleaning rate (approximately 2.9 μm/min) and very good deposition uniformity (less than ±2.0%), which are better than conventional shower plates.

Although the preferred hole machining area diameter range was found to be between 285 mm and 310 mm for susceptors configured to process 300 mm substrates, other hole machining area diameters may be used for substrates of other sizes. In particular, it has been found that a hole machining area having a diameter between about 0.95 and 1.05 times the diameter of the substrate produces very good cleaning rates and deposited film thickness uniformity. In a preferred embodiment, the ratio of the diameter of a hole machining area is between 0.977 and 1.027 times the diameter of the substrate. Accordingly, when a 300 mm substrate is processed, the hole machining area 302 may have a diameter between 285 mm and 315 mm, and more preferably, a diameter between 293.1 mm and 308.1 mm. For processing 450 mm substrates, the hole machining area 302 may have a diameter between 427.5 mm and 472.5 mm, more preferably between 439.7 mm and 462.2 mm. For processing 200 mm substrates, the hole machining area 302 may have a diameter between 190 and 210 mm, more preferably between 195.4 mm and 205.4 mm.

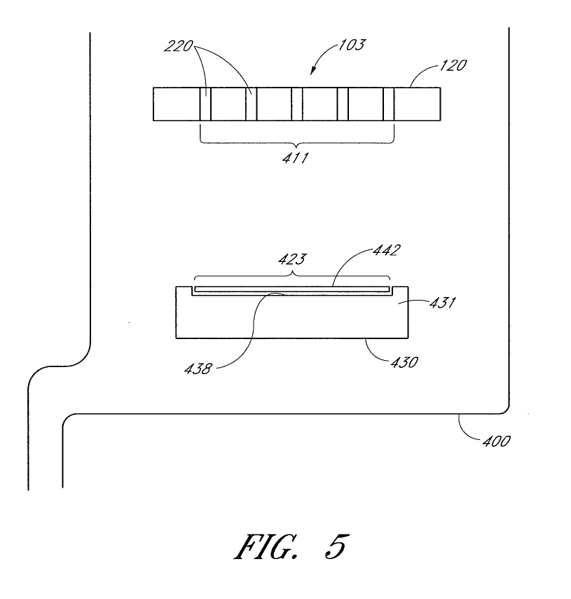

FIG. 5 illustrates the inside of a reaction chamber 400 having a susceptor 430, a wafer 422 resting on the susceptor, and an improved shower plate 120 in accordance with one embodiment. The susceptor 430 may be of various shapes and sizes. In one embodiment, and as shown in FIG. 5, the susceptor 430 includes a substrate confining structure, such as an annular shoulder or wall 431 that defines a pocket or recess 438 in which the wafer 422 closely fits. The diameter of the recess 438 may also vary, depending on the size of the wafer 422 that the susceptor 430 is designed to support. In another embodiment, the susceptor 430 may be flat and without a recess. Also illustrated in FIG. 5 is a surface area 411 of the hole machining area 103 and a surface area 423 of one side of the wafer 422. In one embodiment, the diameter of a circular surface area 411 of the hole machining area 103 is between 0.95 to 1.05 times a diameter of a circular surface area 423 of a side of a largest possible substrate that can fit within the pocket 438. In a preferred embodiment, the diameter of a circular surface area 411 of the hole machining area 103 is between 0.977 and 1.027 times a diameter of a surface area 423 of a side of a largest possible substrate that can fit within the pocket 438.

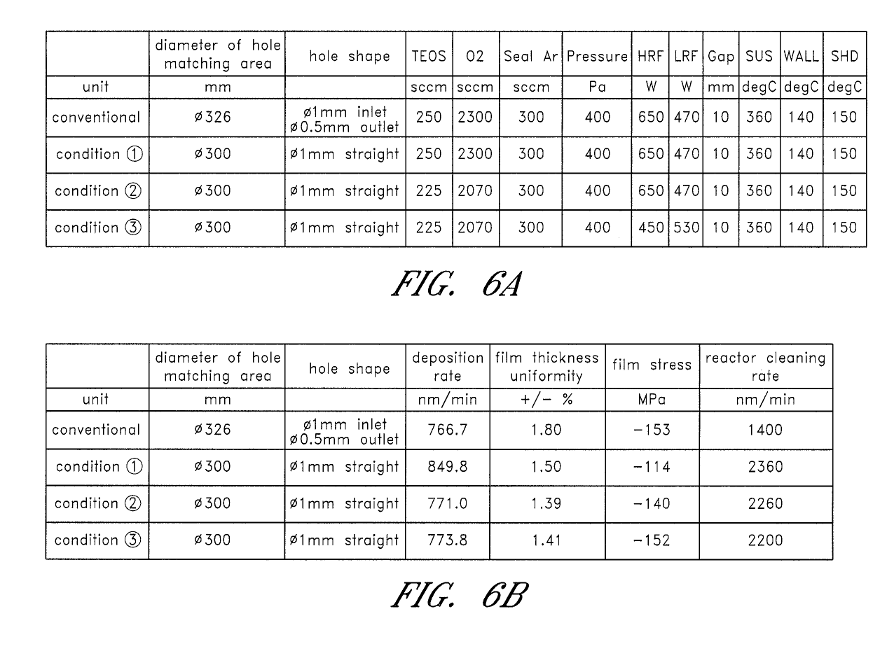

FIGS. 6A and 6B are related charts showing conditions and results of experiments showing the cleaning rate and deposited film thickness uniformity achieved by (1) a conventional shower plate having holes 208 as shown in FIG. 2A and a hole machining area diameter of 326 mm, and (2) an improved shower plate of an embodiment of the present invention, having holes 220 as shown in FIG. 2B and a hole machining area diameter of 300 mm. These experiments were conducted on 300 mm substrates. In these experiments, after deposition of a 1 μm silicon oxide film using TEOS and O₂, the chamber was cleaned using NF₃ and Ar. The chamber cleaning took place under the following conditions: a NF₃ flow rate of 2.2 slm, an Ar flow rate of 5 slm, a distance between the upper electrode and lower electrode of 14 mm, a reaction chamber pressure of 1000 Pa, a remote plasma discharge device power of 2.7 kW, a susceptor temperature of 360° C., a shower plate temperature of 150° C., and a reaction chamber inner wall temperature of 140° C. Under these conditions, a cleaning of the reaction chamber took place for approximately 43 seconds.

FIG. 6A is a chart showing the conditions of experiments in which reaction source gases, TEOS and O₂, were introduced into a reaction chamber to form a TEOS oxide film. This reaction was performed using a conventional shower plate (row 1), and an improved shower plate under three different conditions (rows 2-4). Adjustable variables include flow rates of the reaction gases, chamber pressure (“pressure”), high radio-frequency power (“HRF”), low radio-frequency power (“LRF”), the distance between the upper and lower electrodes in the reaction chamber (“Gap”), the susceptor temperature (“SUS”), the chamber wall temperature (“WALL”) and the shower plate temperature (“SHD”). As shown in row 2 of FIG. 6A, the first condition in which the TEOS was introduced into the reaction chamber using the improved shower plate was in all respects the same as the run using the conventional shower plate (e.g. same reactant flow rates, pressure, temperature and radio-frequency energy levels). Under the second condition (row 3), the flow rates of TEOS and O₂ source gases were reduced by 10% from the first condition to reduce gas consumption. Under the third condition (row 4), the reduced flow rates of the source gases were maintained to reduce gas consumption, and the high and low radio-frequency power levels, HRF and LRF, were adjusted. By adjusting the radio-frequency powers, this yielded a film stress that was approximately the same as the film stress under conventional conditions (as shown in FIG. 6B).

FIG. 6B is a chart showing the resulting cleaning rate and deposited film thickness uniformity on 300 mm wafers achieved by using the conventional shower plate and improved shower plate under the three conditions described in FIG. 6A. Under all three conditions, the improved shower plate yielded a faster deposition rate and a much higher reactor cleaning rate than the conventional shower plate. Moreover, the improved shower plate, having a decreased hole machining area diameter, also exhibited an improved film thickness uniformity over the conventional shower plate, each instance being less than or equal to 1.5%.

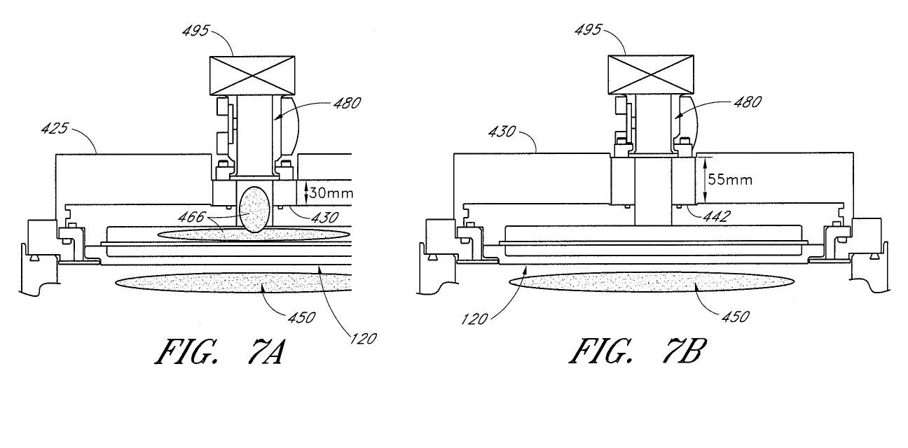

As described above, it is possible to achieve a high cleaning rate by modifying the shower plate to have holes of uniform cross-section, such as a uniform diameter (e.g. 1 mm). Besides the problem of reduced film thickness uniformity, which can be improved by reducing the hole machining area to an appropriate diameter, an additional problem involving parasitic plasma, or abnormal plasma, arises when using the improved shower plate with uniform cross-section holes instead of the conventional shower plate. The problem is illustrated in FIG. 7A and discussed below.

FIG. 7A shows an upper portion of a CVD apparatus 425 having a shower plate 120 of the present invention and a conventional 30 mm ceramic conduit 430 connected above the shower plate. The upper portion of the conduit 430 is connected to an aluminum conduit 480, which is further connected to an isolation valve 495. During the processing stage, in which reaction gas is conveyed into the reaction chamber and activated into an in situ plasma, normal deposition plasma 450 develops beneath the shower plate 120, while parasitic plasma 466 develops above the shower plate 120 in the conduit 430 and in a horizontal plenum defined between the shower plate and the ceiling of the reaction chamber. Although parasitic plasma occurs in CVD reactors having conventional shower plates with non-uniform holes, such as the holes 208 shown in FIG. 2A, the amount of parasitic plasma 466 is generally at a tolerable level that does not adversely affect the film deposition in the reaction chamber. However, by modifying the shower plates to have holes with a bigger diameter (such as holes 220 of FIG. 2B), the amount of parasitic plasma 466 tends to increase, which is undesired during wafer processing.

One way to remedy the increase in parasitic plasma caused by the modified shower plate is to modify the conduit 430 that is used in conventional systems. FIG. 7B illustrates a close up of an upper portion of a CVD apparatus 430 having a modified conduit 442 made of a ceramic material mounted above the shower plate 120. The ceramic conduit 442 is longer than the conventional conduit 430. When a longer ceramic conduit is used, the distance between the RF ground and the upper part of the shower plate (the RF loaded portion) is increased, such that the strength of the electric field decreases, resulting in less parasitic plasma being generated above the shower plate 120. The length of the improved ceramic conduit 442 is preferably greater than the length of the conduit 430 used in conventional CVD apparatuses, which is typically about 30 mm. However, in an embodiment, the improved ceramic conduit 442 is greater than 35 mm, more preferably greater than 45 mm, and in one particular embodiment, about 55 mm to ensure that even if straight, uniformly sized holes are used, the risk of parasitic plasma is very low.

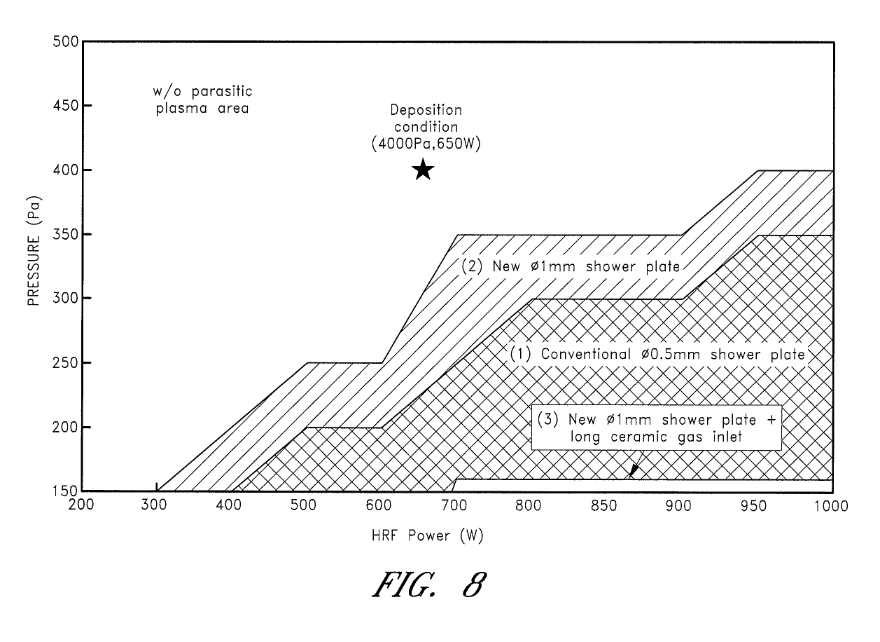

FIG. 8 is a graph illustrating the presence or absence of parasitic plasma generated during wafer processing under certain conditions, namely a range of combinations of reaction chamber pressure (vertical-axis) and high radio-frequency (HRF) power (horizontal-axis), when using (1) a conventional shower plate with holes 208 (FIG. 2A) and a conventional ceramic conduit, (2) a shower plate of one embodiment of the present invention with holes 220 (FIG. 2B) and a conventional ceramic conduit, and (3) a shower plate of one embodiment of the present invention with holes 220 (FIG. 2B) and a longer ceramic conduit as shown in FIG. 7B. As illustrated in the graph, the use of a longer conduit greatly reduced the presence of parasitic plasma generated during wafer processing such that it is possible to perform deposition processes at much lower reaction chamber pressures (e.g., 200 Pa) and higher HRF levels (e.g., 700 W) than when using conventional, shorter length ceramic conduits.

It will be apparent to those skilled in the art that various modifications and variations can be made in the present invention without departing from the scope or spirit of the invention. Thus, it is intended that the present invention cover the modifications and variations of this invention provided that they come within the scope of the appended claims or their equivalents.

What is claimed is:

1. A method of cleaning a CVD processing chamber after processing a wafer, using a remote plasma-discharge device, comprising:
removing the processed wafer from a susceptor in the chamber;
supplying cleaning gas to the remote plasma discharge device;
using plasma energy to activate the cleaning gas in the remote plasma discharge device; and
conveying the activated cleaning gas into the chamber and through a plurality of holes of a shower plate facing the susceptor, the holes extending completely through the shower plate, the holes each having a uniform cross-sectional area, wherein a diameter of a smallest circular area of the shower plate having all of the holes is 0.95 to 1.05 times a diameter the wafer.

2. The method of claim 1, further comprising:
allowing the cleaning gas to react with film deposits on surfaces of the chamber and remove said film deposits from the surfaces of the chamber; and
discharging the film deposits through an outlet port of the chamber.

3. The method of claim 1, wherein the cleaning gas removes film deposits from surfaces of the chamber at a rate greater than 2200 nm/min.

4. A method of processing a substrate in a chamber, comprising:
placing the substrate on a susceptor in the chamber; and
supplying a reaction gas into the chamber and through a plurality of holes of a shower plate facing the susceptor, the holes extending completely through the shower plate, the holes each having a uniform cross-sectional area, wherein a diameter of a smallest circular area of the shower plate having all of the holes is 0.95 to 1.05 times a diameter of the substrate.

5. The method of claim 4, further comprising exciting the reaction gas to a plasma state in the chamber.

6. A plasma CVD apparatus, comprising:
a plasma CVD reaction chamber;
a susceptor for supporting a substrate thereon, the susceptor disposed inside the reaction chamber and configured to be used as a first electrode to generate a plasma;
a shower plate used as a second electrode to generate said plasma, the shower plate facing the susceptor and having a plurality of holes extending through the shower plate, the holes each having a uniform cross-sectional area, wherein a diameter of a smallest circular area of the shower plate having all of the holes is 0.95 to 1.05 times a diameter of a largest possible substrate that can fit within a confining structure of the susceptor; and
one or more power sources electrically connected to the shower plate.

7. The apparatus of claim 6, wherein the confining structure comprises an annular wall of a pocket for holding a substrate.

8. The apparatus of claim 6, further comprising a ceramic conduit mounted above an inlet leading into the shower plate, said conduit being greater than 35 mm.

9. A shower plate for use in a plasma CVD device, comprising:
a plate having an electrically conductive extension configured to be connected to a power source to enable the plate to act as an electrode; and
a plurality of holes extending through the plate and each having a uniform cross-sectional area.

10. The shower plate of claim 9, wherein said holes form a spiral pattern along sides of the shower plate.

11. The shower plate of claim 9, wherein a smallest circular area of a surface of the plate having all of the holes has a diameter between 285 and 310 mm.

12. The shower plate of claim 9, wherein a smallest circular area of a surface of the plate having all of the holes has a diameter between 190 and 210 mm.

13. The shower plate of claim 9, wherein a smallest circular area of a surface of the plate having all of the holes has a diameter between 427.5 and 472.5 mm.
